(19) United States
(12) Patent Application Publication
(10) Pub. No.: US 2025/0273626 A1
(43) Pub. Date: Aug. 28, 2025

(54) PACKAGE COMPRISING INTEGRATED DEVICES AND AN INTERCONNECTION DEVICE

(71) Applicant: QUALCOMM Incorporated, San Diego, CA (US)

(72) Inventors: Aniket PATIL, San Diego, CA (US); Manuel ALDRETE, Encinitas, CA (US); Piyush GUPTA, San Diego, CA (US); Joan Rey Villarba BUOT, Escondido, CA (US); Yangyang SUN, San Diego, CA (US); Hong Bok WE, San Diego, CA (US)

(21) Appl. No.: 18/590,303

(22) Filed: Feb. 28, 2024

(51) Int. Cl. H01L 25/065; H01L 23/00; H01L 23/31; H01L 23/48; H01L 23/498; H01L 25/00

(52) U.S. Cl. CPC H01L 25/0652; H01L 23/3121; H01L 23/481; H01L 23/49838; H01L 24/16; H01L 25/50; H01L 2224/16225; H01L 2224/16258; H01L 2924/181

(57) ABSTRACT

A package comprising a first substrate; a first integrated device coupled to the first substrate through at least a first plurality of solder interconnects, wherein the first integrated device comprises a plurality of through substrate vias; an interconnection device coupled to a back side of the first integrated device through a second plurality of solder interconnects; a second substrate coupled to the first substrate through at least a third plurality of solder interconnects; and a second integrated device coupled to the second substrate and the interconnection device.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. There is also an ongoing need to reduce the overall size of the packages.

### SUMMARY

Various features relate to packages with substrates and integrated devices.

One example provides a package comprising a first substrate; a first integrated device coupled to the first substrate through at least a first plurality of solder interconnects, wherein the first integrated device comprises a plurality of through substrate vias; an interconnection device coupled to a back side of the first integrated device through a second plurality of solder interconnects; a second substrate coupled to the first substrate through at least a third plurality of solder interconnects; and a second integrated device coupled to the second substrate and the interconnection device.

Another example provides a method for fabricating a package. The method provides a first substrate. The method couples a first integrated device to the first substrate through at least a first plurality of solder interconnects, wherein the first integrated device comprises a plurality of through substrate vias. The method couples an interconnection device to a back side of the first integrated device through a second plurality of solder interconnects. The method couples a second substrate to the first substrate through at least a third plurality of solder interconnects. The method couples a second integrated device to the second substrate and the interconnection device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate and an interconnection device.

FIG. 2 illustrates an exemplary cross sectional profile view of a package that includes a substrate and an interconnection device.

FIG. 3 illustrates an exemplary cross sectional profile view of a package that includes a substrate and an interconnection device.

FIG. 4 illustrates an exemplary cross sectional profile view of an interconnection device.

FIG. 5 illustrates an exemplary cross sectional profile view of an integrated device.

FIGS. 6A-6C illustrate an exemplary sequence for fabricating an interconnection device.

FIGS. 7A-7D illustrate an exemplary sequence for fabricating a package that includes a substrate and an interconnection device.

FIGS. 8A-8D illustrate an exemplary sequence for fabricating a package that includes a substrate and an interconnection device.

FIG. 9 illustrates an exemplary flow chart of a method for fabricating a package that includes a substrate and an interconnection device.

FIGS. 10A-10C illustrate an exemplary sequence for fabricating a substrate.

FIG. 11 illustrates an exemplary sequence for fabricating a substrate with an interconnection device.

FIG. 12 illustrates an exemplary flow chart of a method for fabricating a substrate.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first substrate; a first integrated device coupled to the first substrate through at least a first plurality of solder interconnects, wherein the first integrated device comprises a plurality of through substrate vias; an interconnection device coupled to a back side of the first integrated device through a second plurality of solder interconnects; a second substrate coupled to the first substrate through at least a third plurality of solder interconnects; and a second integrated device coupled to the second substrate and the interconnection device. As will be further described below, the interconnection device provides electrical connectivity between integrated device, while maintaining and/or improving the thermal performance of the package and/or the power distribution network performance of the package.

### Exemplary Package Comprising an Interconnection Device

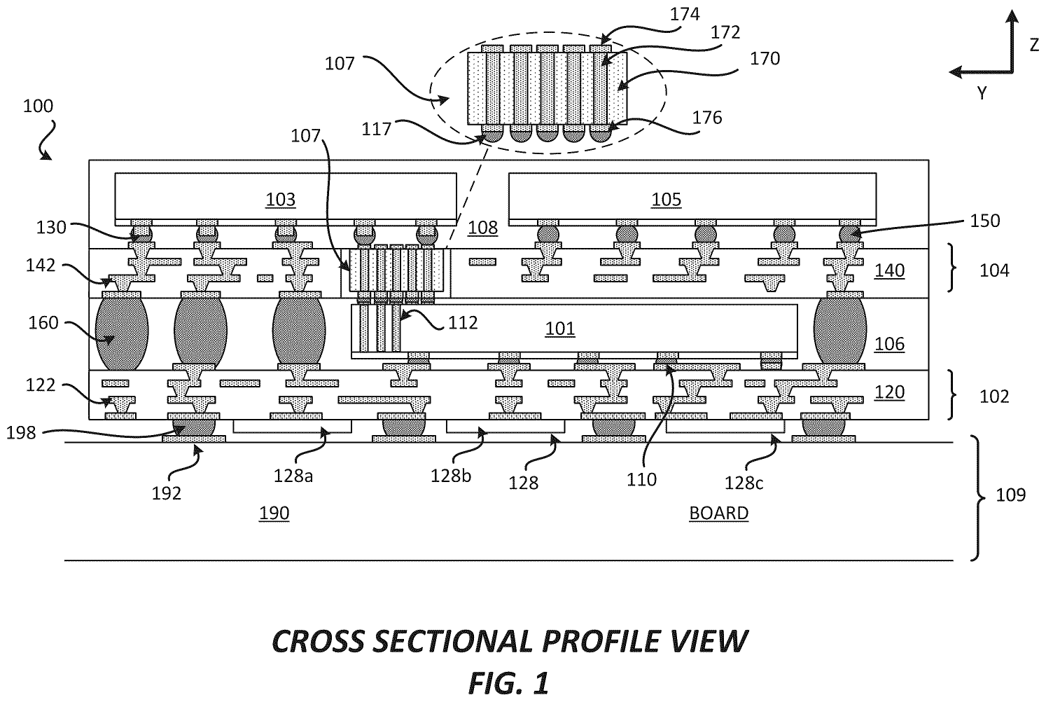

FIG. 1 illustrates a cross sectional profile view of a package 100 that includes an interconnection device. The package 100 may be a package on package (PoP). The package 100 is coupled to a board 109 through a plurality of solder interconnects 198. The board 109 includes at least one board dielectric layer 190 and a plurality of board interconnects 192. The board 109 may include a printed circuit board (PCB). The package 100 includes a substrate 102, a substrate 104, an integrated device 101, an integrated device 103, an integrated device 105, an interconnection device 107, an encapsulation layer 106 and an encapsulation layer 108.

The substrate 102 may be a first substrate (e.g., bottom substrate). The substrate 102 includes at least one dielectric layer 120, and a plurality of interconnects 122. The at least one dielectric layer 120 may include at least one first dielectric layer. The substrate 104 may be a second substrate (e.g., top substrate). The substrate 104 includes at least one dielectric layer 140 and a plurality of interconnects 142. The at least one dielectric layer 140 may include at least one second dielectric layer.

The interconnection device 107 is located at least partially in the substrate 104. For example, the interconnection device 107 may be at least partially embedded in the substrate 104. The interconnection device 107 includes an interconnection substrate layer 170, a plurality of vias 172, a plurality of pads 174 and a plurality of pads 176. The plurality of vias 172, the plurality of pads 174 and/or the plurality of pads 176 may be part of interconnects of the interconnection device 107. The interconnection substrate layer 170 may include silicon (Si). In some implementations, the interconnects of the interconnection device 107 may have a pitch that is equal or less than the pitch of the interconnects of the substrate 102 and/or the pitch of the interconnects of the substrate 104. The at least one dielectric layer 140 may touch the interconnection substrate layer 170.

The integrated device 101 may be a first integrated device. The integrated device 101 includes a plurality of through substrate vias 112. The integrated device 103 may be coupled to the substrate 102 through at least a plurality of solder interconnects 110. The integrated device 101 may be coupled to the interconnects from the plurality of interconnects 122 through the plurality of solder interconnects 110. The plurality of solder interconnects 110 may be touching interconnects from the plurality of interconnects 122. The front side of the integrated device 101 is closer to the substrate 102 than the back side of the integrated device 101 is to the substrate 102. The back side of the integrated device 101 is closer to the substrate 104 than the front side of the integrated device 101 is to the substrate 104.

The substrate 104 is coupled to the substrate 102 through a plurality of solder interconnects 160. The plurality of solder interconnects 160 are located between the substrate 102 and the substrate 104. The plurality of solder interconnects 160 are coupled to the plurality of interconnects 122 and the plurality of interconnects 142.

The encapsulation layer 106 is located between the substrate 102 and the substrate 104. The encapsulation layer 106 may at least partially encapsulate the integrated device 101 and the plurality of solder interconnects 160. The encapsulation layer 106 may touch the substrate 102, the substrate 104, the integrated device 101, the plurality of solder interconnects 160 and/or the plurality of solder interconnects 117. The encapsulation layer 106 may be located between the substrate 104 and the back side of the integrated device 101. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

The interconnection device 107 is coupled to the integrated device 101 through the plurality of solder interconnects 117. The plurality of solder interconnects 117 may be coupled to the plurality of through substrate vias 112 and the plurality of pads 176. In some implementations, a metallization portion is coupled to the back side of the integrated device 101. The metallization portion may include a plurality of metallization interconnects that are coupled to the plurality of through substrate vias 112. In such instances, the plurality of solder interconnects 117 may be coupled to the plurality of metallization interconnects.

The integrated device 105 is coupled to the substrate 104 through a plurality of solder interconnects 150. The plurality of solder interconnects 150 may touch interconnects from the plurality of interconnects 142. The integrated device 103 is coupled to the substrate 104 through a plurality of solder interconnects 130. The integrated device 103 is coupled to the interconnection device 107 through the plurality of solder interconnects 130. Some of the solder interconnects from the plurality of solder interconnects 130 may touch interconnects from the plurality of interconnects 142 of the substrate 104. Some of the solder interconnects from the plurality of solder interconnects 130 may touch interconnects (e.g., plurality of pads 174) of the interconnection device 107. The interconnection device 107 may at least partially vertically overlap with the integrated device 101 and the integrated device 103. In some implementations, a plurality of pillar interconnects may be coupled to the integrated device 103. In such instances, the plurality of solder interconnects 130 may be coupled to the plurality of pillar interconnects.

The encapsulation layer 108 is coupled to the substrate 104. The encapsulation layer 108 may at least partially encapsulate the integrated device 103 and the integrated device 105. The encapsulation layer 108 may touch the substrate 104, the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The use of the interconnection device 107 helps improve the performance of the package 100, including improving the thermal performance and power distribution network performance of the package, while providing a compact form factor for the package 100. For example, the interconnection device 107 helps provide high density electrical paths between integrated devices, which may help improve the overall performance of the package 100.

An electrical path between the integrated device 101 and the integrated device 103 may include (i) at least one through substrate via from the plurality of through substrate vias 112, (ii) a solder interconnect from the plurality of solder interconnects 117, (iii) a pad from the plurality of pads 176, (iv) a via from the plurality of vias 172, (v) a pad from the plurality of pads 174, and/or (vi) a solder interconnect from the plurality of solder interconnects 130.

In the event the integrated device 101 includes a back side metallization portion, the above electrical path may also include metallization interconnects from the metallization portion. Thus, an electrical path between the integrated device 101 and the integrated device 103 may include (i) at least one through substrate via from the plurality of through substrate vias 112, (ii) at least one metallization interconnect from a metallization portion, (iii) a solder interconnect from the plurality of solder interconnects 117, (iv) a pad from the plurality of pads 176, (v) a via from the plurality of vias 172, (vi) a pad from the plurality of pads 174, and/or (vii) a solder interconnect from the plurality of solder interconnects 130.

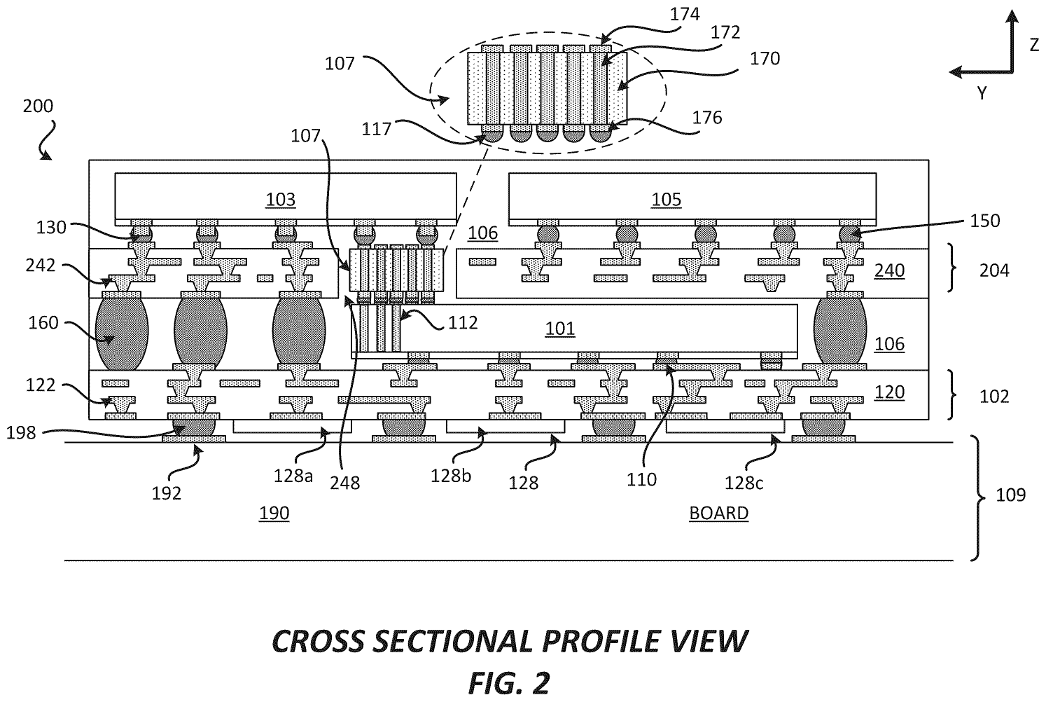

FIG. 2 illustrates a cross sectional profile view of a package 200 that includes an interconnection device. The package 200 may be a package on package (PoP). The package 200 may be similar to the package 100 and include similar components as the package 100. The package 200 is coupled to a board 109 through a plurality of solder interconnects 198. The board 109 includes at least one board dielectric layer 190 and a plurality of board interconnects 192. The board 109 may include a printed circuit board (PCB). The package 200 includes a substrate 102, a substrate 204, an integrated device 101, an integrated device 103, an integrated device 105, an interconnection device 107, an encapsulation layer 106 and an encapsulation layer 108.

The substrate 102 may be a first substrate (e.g., bottom substrate). The substrate 102 includes at least one dielectric layer 120, and a plurality of interconnects 122. The at least one dielectric layer 120 may include at least one first dielectric layer. The substrate 204 may be a second substrate (e.g., top substrate). The substrate 204 includes at least one dielectric layer 240 and a plurality of interconnects 242. The at least one dielectric layer 240 may include at least one second dielectric layer. The substrate 204 may include at least one cavity 248.

The interconnection device 107 is located at least partially in the cavity 248 of the substrate 204. The interconnection device 107 includes an interconnection substrate layer 170, a plurality of vias 172, a plurality of pads 174 and a plurality of pads 176. The plurality of vias 172, the plurality of pads 174 and/or the plurality of pads 176 may be part of interconnects of the interconnection device 107. In some implementations, the interconnects of the interconnection device 107 may have a pitch that is equal or less than the pitch of the interconnects of the substrate 102 and/or the pitch of the interconnects of the substrate 204.

The integrated device 101 may be a first integrated device. The integrated device 101 includes a plurality of through substrate vias 112. The integrated device 103 may be coupled to the substrate 102 through at least a plurality of solder interconnects 110. The integrated device 101 may be coupled to the interconnects from the plurality of interconnects 122 through the plurality of solder interconnects 110. The plurality of solder interconnects 110 may be touching interconnects from the plurality of interconnects 122. The front side of the integrated device 101 is closer to the substrate 102 than the back side of the integrated device 101 is to the substrate 102. The back side of the integrated device 101 is closer to the substrate 204 than the front side of the integrated device 101 is to the substrate 204.

The substrate 204 is coupled to the substrate 102 through a plurality of solder interconnects 160. The plurality of solder interconnects 160 are located between the substrate 102 and the substrate 204. The plurality of solder interconnects 160 are coupled to the plurality of interconnects 122 and the plurality of interconnects 242.

The interconnection device 107 is coupled to the integrated device 101 through the plurality of solder interconnects 117. The plurality of solder interconnects 117 may be coupled to the plurality of through substrate vias 112 and the plurality of pads 176. In some implementations, a metallization portion is coupled to the back side of the integrated device 101. The metallization portion may include a plurality of metallization interconnects that are coupled to the plurality of through substrate vias 112. In such instances, the plurality of solder interconnects 117 may be coupled to the plurality of metallization interconnects.

The integrated device 105 is coupled to the substrate 204 through a plurality of solder interconnects 150. The plurality of solder interconnects 150 may touch interconnects from the plurality of interconnects 242. The integrated device 103 is coupled to the substrate 204 through a plurality of solder interconnects 130. The integrated device 103 is coupled to the interconnection device 107 through the plurality of solder interconnects 130. Some of the solder interconnects from the plurality of solder interconnects 130 may touch interconnects from the plurality of interconnects 242 of the substrate 204. Some of the solder interconnects from the plurality of solder interconnects 130 may touch interconnects (e.g., plurality of pads 174) of the interconnection device 107. The interconnection device 107 may at least partially vertically overlap with the integrated device 101 and the integrated device 103.

The encapsulation layer 106 is located between the substrate 102 and the substrate 204. The encapsulation layer 106 may at least partially encapsulate the integrated device 101 and the plurality of solder interconnects 160. The encapsulation layer 106 may be located between the substrate 204 and the back side of the integrated device 101. The encapsulation layer 106 may located at least partially in the cavity 248 of the substrate 204. The encapsulation layer 106 may at least partially encapsulate the interconnection device 107. The encapsulation layer 106 may at least partially encapsulate the integrated device 103 and the integrated device 105. The encapsulation layer 106 may touch the substrate 102, the substrate 204, the integrated device 101, the plurality of solder interconnects 160, the plurality of solder interconnects 117, the interconnection device 107, the integrated device 103 and/or the integrated device 105. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

The use of the interconnection device 107 helps improve the performance of the package 100, including improving the thermal performance and power distribution network performance of the package, while providing a compact form factor for the package 100. For example, the interconnection device 107 helps provide high density electrical paths between integrated devices, which may help improve the overall performance of the package 100.

An electrical path between the integrated device 101 and the integrated device 103 may include (i) at least one through substrate via from the plurality of through substrate vias 112, (ii) a solder interconnect from the plurality of solder interconnects 117, (iii) a pad from the plurality of pads 176, (iv) a via from the plurality of vias 172, (v) a pad from the plurality of pads 174, and/or (vi) a solder interconnect from the plurality of solder interconnects 130.

In the event the integrated device 101 includes a back side metallization portion, the above electrical path may also include metallization interconnects from the metallization portion. Thus, an electrical path between the integrated device 101 and the integrated device 103 may include (i) at least one through substrate via from the plurality of through substrate vias 112, (ii) at least one metallization interconnect from a metallization portion, (iii) a solder interconnect from the plurality of solder interconnects 117, (iv) a pad from the plurality of pads 176, (v) a via from the plurality of vias 172, (vi) a pad from the plurality of pads 174, and/or (vii) a solder interconnect from the plurality of solder interconnects 130.

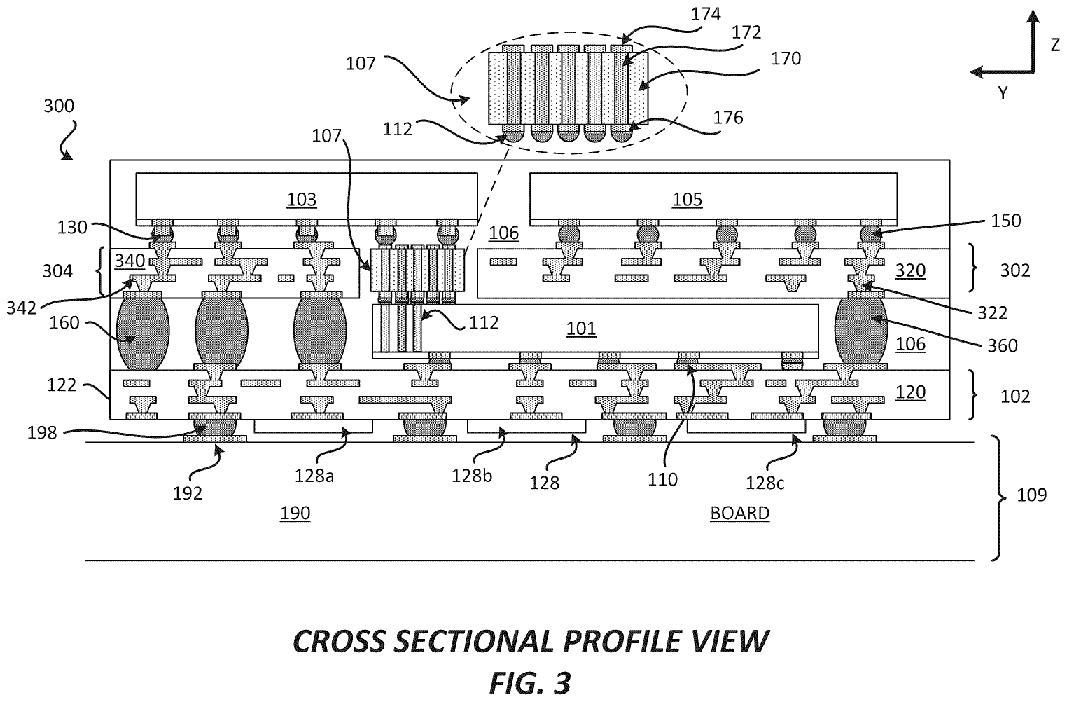

In some implementations, the substrate 204 of FIG. 2 may be replaced with two or more substrates. FIG. 3 illustrates a cross sectional profile view of a package 300 that includes an interconnection device. The package 300 may be a package on package (PoP). The package 300 may be similar to the package 200 and include similar components as the package 200. The package 300 is coupled to a board 109 through a plurality of solder interconnects 198. The board 109 includes at least one board dielectric layer 190 and a plurality of board interconnects 192. The board 109 may include a printed circuit board (PCB). The package 300 includes a substrate 102, a substrate 302, a substrate 304, an integrated device 101, an integrated device 103, an integrated device 105, an interconnection device 107, an encapsulation layer 106 and an encapsulation layer 108.

The substrate 102 may be a first substrate (e.g., bottom substrate). The substrate 102 includes at least one dielectric layer 120, and a plurality of interconnects 122. The at least one dielectric layer 120 may include at least one first dielectric layer. The substrate 204 may be a second substrate (e.g., top substrate). The substrate 302 includes at least one dielectric layer 320 and a plurality of interconnects 322. The at least one dielectric layer 320 may include at least one second dielectric layer. The substrate 304 includes at least one dielectric layer 340 and a plurality of interconnects 342. The at least one dielectric layer 340 may include at least one third dielectric layer.

The interconnection device 107 is located laterally between the substrate 302 and the substrate 304. The interconnection device 107 includes an interconnection substrate layer 170, a plurality of vias 172, a plurality of pads 174 and a plurality of pads 176. The plurality of vias 172, the plurality of pads 174 and/or the plurality of pads 176 may be part of interconnects of the interconnection device 107. In some implementations, the interconnects of the interconnection device 107 may have a pitch that is equal or less than the pitch of the interconnects of the substrate 102, the pitch of the interconnects of the substrate 302 and/or the pitch of the interconnects of the substrate 304.

The integrated device 101 may be a first integrated device. The integrated device 101 includes a plurality of through substrate vias 112. The integrated device 103 may be coupled to the substrate 102 through at least a plurality of solder interconnects 110. The integrated device 101 may be coupled to the interconnects from the plurality of interconnects 122 through the plurality of solder interconnects 110. The plurality of solder interconnects 110 may be touching interconnects from the plurality of interconnects 122. The front side of the integrated device 101 is closer to the substrate 102 than the back side of the integrated device 101 is to the substrate 102. The back side of the integrated device 101 is closer to the substrate 204 than the front side of the integrated device 101 is to the substrate 204.

The substrate 302 is coupled to the substrate 102 through a plurality of solder interconnects 360. The plurality of solder interconnects 360 are located between the substrate 102 and the substrate 302. The plurality of solder interconnects 360 are coupled to the plurality of interconnects 122 and the plurality of interconnects 342.

The substrate 304 is coupled to the substrate 102 through a plurality of solder interconnects 160. The plurality of solder interconnects 160 are located between the substrate 102 and the substrate 304. The plurality of solder interconnects 160 are coupled to the plurality of interconnects 122 and the plurality of interconnects 342.

The interconnection device 107 is coupled to the integrated device 101 through the plurality of solder interconnects 117. The plurality of solder interconnects 117 may be coupled to the plurality of through substrate vias 112 and the plurality of pads 176. In some implementations, a metallization portion is coupled to the back side of the integrated device 101. The metallization portion may include a plurality of metallization interconnects that are coupled to the plurality of through substrate vias 112. In such instances, the plurality of solder interconnects 117 may be coupled to the plurality of metallization interconnects.

The integrated device 105 is coupled to the substrate 302 through a plurality of solder interconnects 150. The plurality of solder interconnects 150 may touch interconnects from the plurality of interconnects 242. The integrated device 103 is coupled to the substrate 304 through a plurality of solder interconnects 130. The integrated device 103 is coupled to the interconnection device 107 through the plurality of solder interconnects 130. Some of the solder interconnects from the plurality of solder interconnects 130 may touch interconnects from the plurality of interconnects 342 of the substrate 304. Some of the solder interconnects from the plurality of solder interconnects 130 may touch interconnects (e.g., plurality of pads 174) of the interconnection device 107. The interconnection device 107 may at least partially vertically overlap with the integrated device 101 and the integrated device 103.

The encapsulation layer 106 is located between the substrate 102 and the substrate 302. The encapsulation layer 106 is located between the substrate 102 and the substrate 304. The encapsulation layer 106 may at least partially encapsulate the integrated device 101 and the plurality of solder interconnects 160. The encapsulation layer 106 may be located between the substrate 302 and the back side of the integrated device 101. The encapsulation layer 106 may located at least partially in the cavity 248 of the substrate 204. The encapsulation layer 106 may at least partially encapsulate the interconnection device 107. The encapsulation layer 106 may at least partially encapsulate the integrated device 103 and the integrated device 105. The encapsulation layer 106 may touch the substrate 102, the substrate 302, the substrate 304, the integrated device 101, the plurality of solder interconnects 160, the plurality of solder interconnects 160, the plurality of solder interconnects 117, the interconnection device 107, the integrated device 103 and/or the integrated device 105. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

An electrical path between the integrated device 101 and the integrated device 103 may include (i) at least one through substrate via from the plurality of vias 112, (ii) a solder interconnect from the plurality of solder interconnects 117, (iii) a pad from the plurality of pads 176, (iv) a via from the plurality of vias 172, (v) a pad from the plurality of pads 174, and/or (vi) a solder interconnect from the plurality of solder interconnects 130.

In the event the integrated device 101 includes a back side metallization portion, the above electrical path may also include metallization interconnects from the metallization portion. Thus, an electrical path between the integrated device 101 and the integrated device 103 may include (i) at least one through substrate via from the plurality of through substrate vias 112, (ii) at least one metallization interconnect from a metallization portion, (iii) a solder interconnect from the plurality of solder interconnects 117, (iv) a pad from the plurality of pads 176, (v) a via from the plurality of vias 172, (vi) a pad from the plurality of pads 174, and/or (vii) a solder interconnect from the plurality of solder interconnects 130.

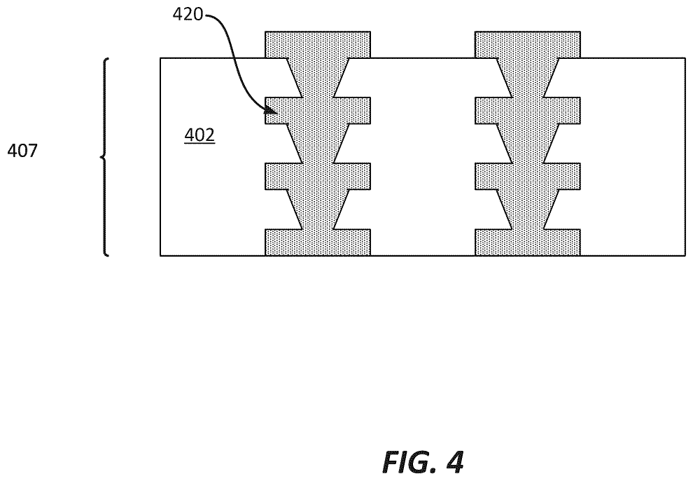

Different implementations may use different interconnection devices. FIG. 4 illustrates a cross sectional profile view of an interconnection device 407. The interconnection device 407 may replace or be used in conjunction with the interconnection device 107. The interconnection device 407 includes at least one dielectric layer 402 and a plurality of interconnects 420. The plurality of interconnects 420 may include vias, traces and/or pads. The interconnection device 407 may be implemented as a substrate (e.g., embedded trace substrate). The interconnection device 407 may be implemented as a redistribution portion substrate.

### Exemplary Integrated Device

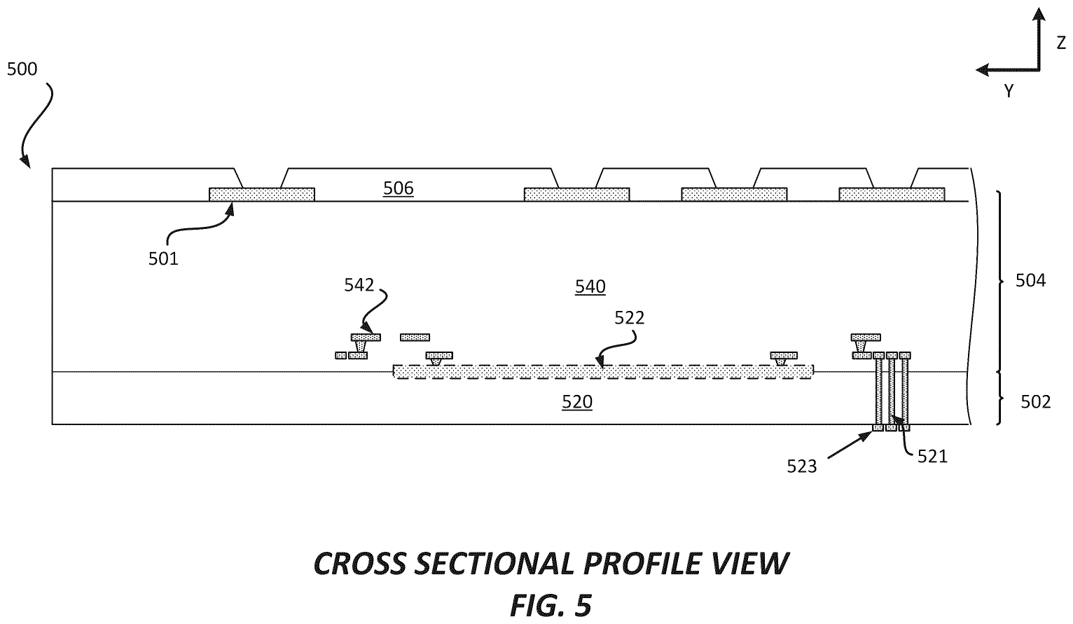

FIG. 5 illustrates a cross sectional profile view of an integrated device 500 that includes a die substrate. The integrated device 500 may represent the integrated device 101, the integrated device 103 and/or the integrated device 105. The integrated device 500 includes a die substrate portion 502 and a die interconnection portion 504. The die substrate portion 502 includes a die substrate 520, an active region 522 and a plurality of through substrate vias 521. The active region 522 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 522 of the die substrate 520.

The die substrate 520 may include silicon (Si). The die substrate 520 may comprise a bulk silicon. The bulk silicon may include a monolith silicon. The plurality of through substrate vias 521 may extend through the die substrate 520. Different implementations may have different thicknesses for the die substrate 520. A metallization portion that includes a plurality of metallization interconnects 523 may be coupled to the plurality of through substrate vias 521. The plurality of metallization interconnects 523 may include a plurality of back side metallization interconnects.

The die interconnection portion 504 includes at least one dielectric layer 540 and a plurality of die interconnects 542. The die interconnection portion 504 is coupled to the die substrate portion 502. The plurality of die interconnects 542 is coupled to the active region 522 of the die substrate portion 502. The plurality of die interconnects 542 may be coupled to the plurality of through substrate vias 521. The die interconnection portion 504 may also include a plurality of pad interconnects 501 and a passivation layer 506. In some implementations, a back end of line (BEOL) process may be used to fabricate the die interconnection portion 504. In some implementations, a front side of the integrated device 500 may be a side that includes the plurality of pad interconnects 501. In some implementations, a back side of the integrated device 500 may be a side that includes the die substrate 520, the plurality of through substrate vias 521 and/or the plurality of metallization interconnects 523.

In some implementations, an electrical path to and/or from an active region 522 may include at least one die interconnect from the plurality of die interconnects 542, at least one through substrate via from the plurality of through substrate vias 521. In some implementations, an electrical path to and/or from an active region 522 may include at least one die interconnect from the plurality of die interconnects 542, at least one pad interconnect from the plurality of pad interconnects 501. A plurality of solder interconnects may be coupled to the plurality of pad interconnects 501.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 300) may be implemented in a radio frequency (RF) package. The RF package may be a radio frequency front end (RFFE) package. A package (e.g., 100, 200, 300) may be configured to provide Wireless Fidelity (WiFi) communication and/or cellular communication (e.g., 2G, 3G, 4G, 5G). The packages (e.g., 100, 200, 300) may be configured to support Global System for Mobile (GSM) Communications, Universal Mobile Telecommunications System (UMTS), and/or Long-Term Evolution (LTE). The packages (e.g., 100, 200, 300) may be configured to transmit and receive signals having different frequencies and/or communication protocols.

### Exemplary Sequence for Fabricating an Interconnection Device

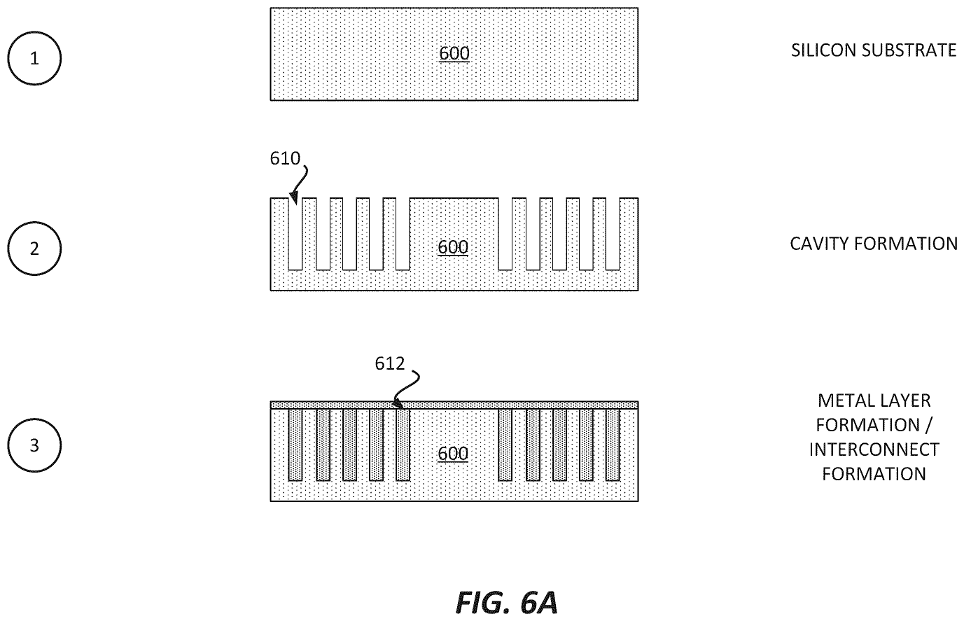

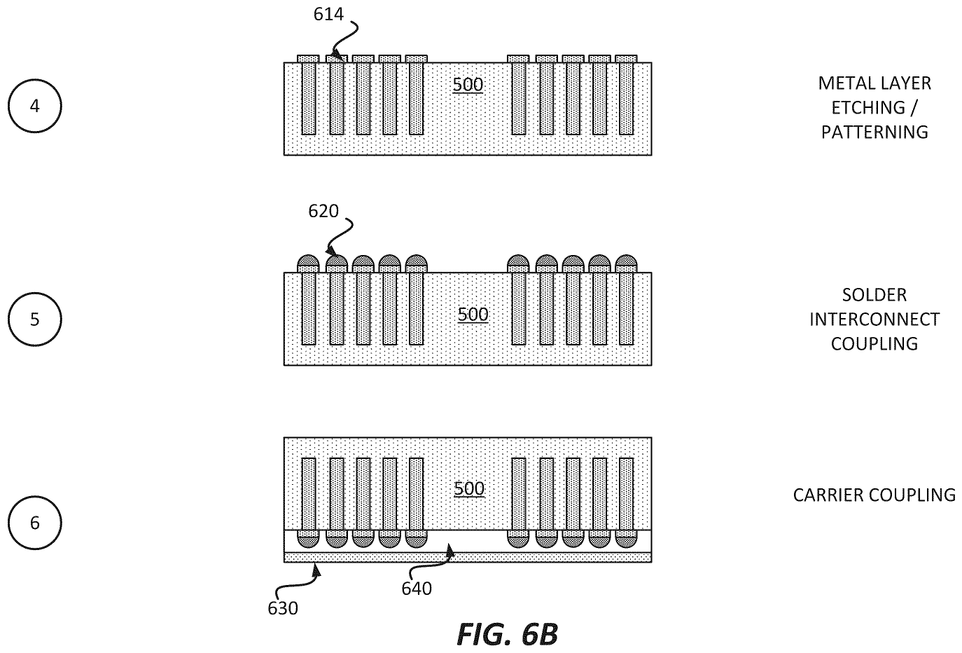

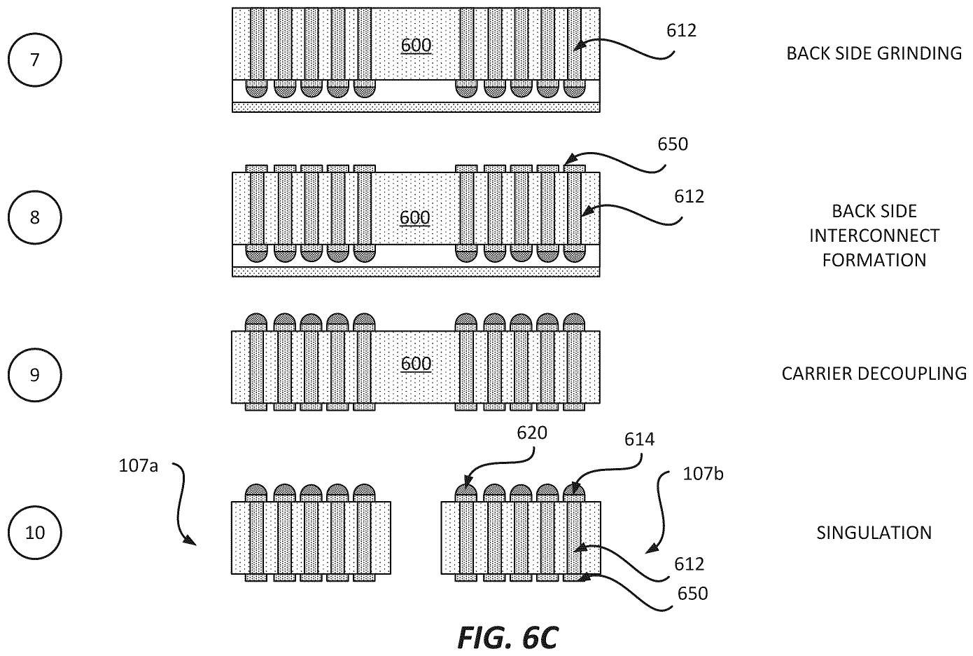

In some implementations, fabricating an interconnection device includes several processes. FIGS. 6A-6C illustrate an exemplary sequence for providing or fabricating an interconnection device. In some implementations, the sequence of FIGS. 6A-6C may be used to provide or fabricate the interconnection device 107.

It should be noted that the sequence of FIGS. 6A-6C may combine one or more stages in order to simplify and/or clarify the sequence for providing or fabricating an interconnection device. In some implementations, the order of the processes may be changed or modified. In some implementations, one or more of processes may be replaced or substituted without departing from the scope of the disclosure.

Stage 1, as shown in FIG. 6A, illustrates a state after a substrate 600 is provided. The silicon substrate 600 may include a silicon substrate.

Stage 2 illustrates a state after a plurality of cavities 610 are formed in the substrate 600. The plurality of cavities 610 may be formed using a laser ablation process.

Stage 3 illustrates a state after a plurality of interconnects 612 are formed. The plurality of interconnects 612 may be formed in the plurality of cavities 610. The plurality of interconnects 612 may include a plurality of vias. In some implementations, a plating process may be used to form the plurality of interconnects 612.

Stage 4 of FIG. 6B, illustrates a state after portions of the plurality of interconnects 612 are patterned to form a plurality of interconnects 614. For example, the plurality of interconnects 614 may include a plurality of pads.

Stage 5 illustrates a state after a plurality of solder interconnects 620 are coupled to the plurality of interconnects 614. A solder reflow process may be used to couple the plurality of solder interconnects 620 to the plurality of interconnects 614.

Stage 6 illustrates a state the substrate 600, the plurality of interconnects 614 and the plurality of solder interconnects 620 are coupled to the carrier 630 through an adhesive 640.

Stage 7, as shown in FIG. 6C, illustrates a state after portions of the substrate 600. Portions of the plurality of interconnects 612 may also be removed. In some implementations, a back side grinding process may be used to remove portions of the substrate 600 and portions of the plurality of interconnects 612.

Stage 8, illustrates a state after a plurality of interconnects 650 are formed. The plurality of interconnects 650 may be coupled to the plurality of interconnects 612. A plating process may be used to form the plurality of interconnects 650. The plurality of interconnects 650 may include a plurality of pads.

Stage 9 illustrates a state after the carrier 630 and the adhesive 640 are decoupled from the substrate 600, the plurality of interconnects 614 and the plurality of solder interconnects 620.

Stage 10 illustrates a state after singulation, where several interconnection devices 107 are formed. Singulation may include slicing and/or cutting the substrate 600. Stage 10 illustrates an interconnection device 107a and an interconnection device 107b.

### Exemplary Sequence for Fabricating a Package

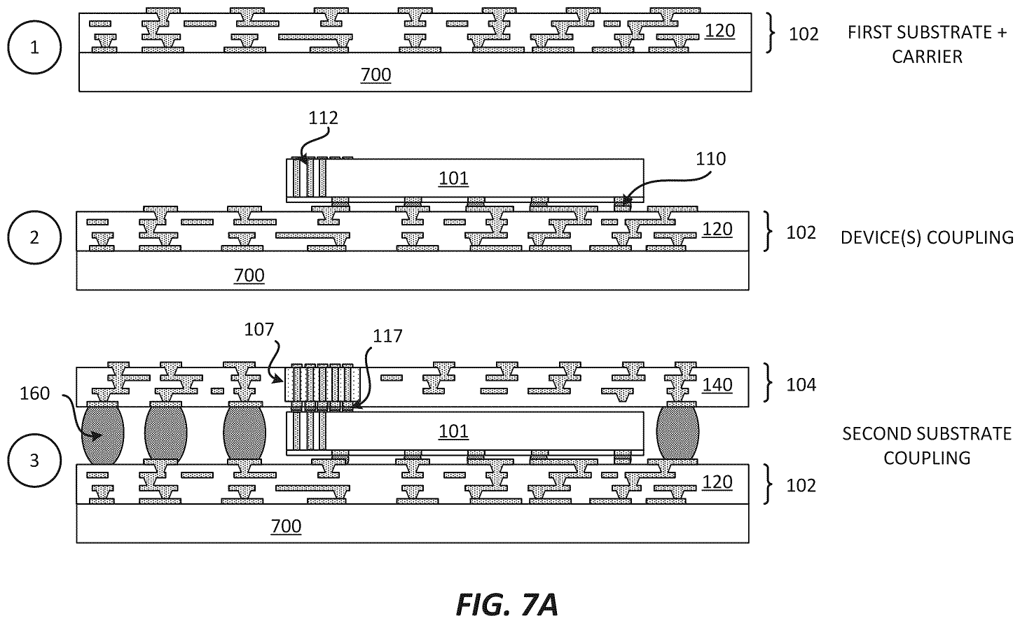

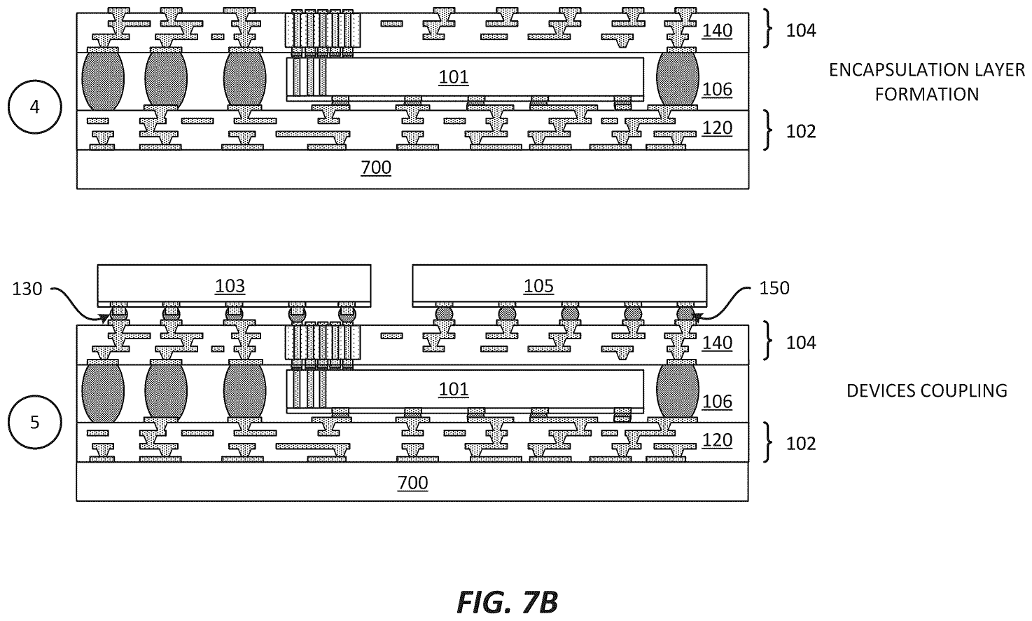

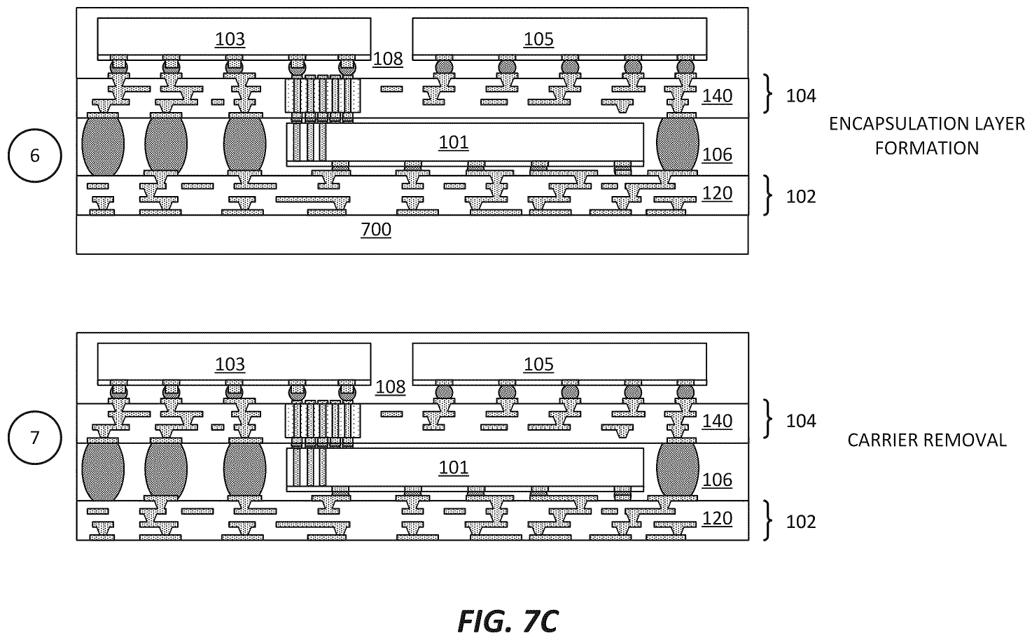

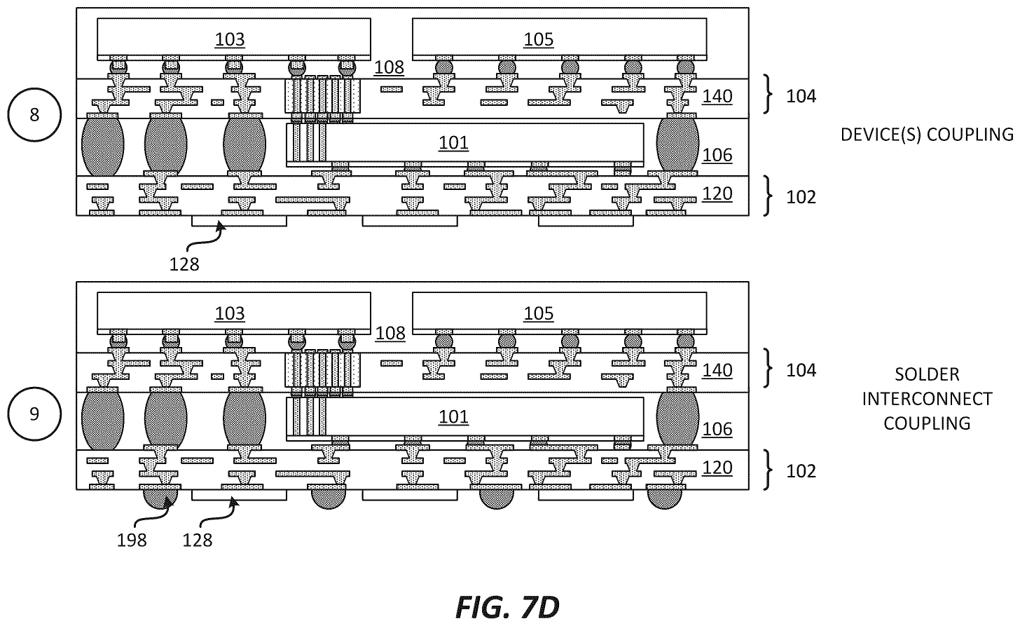

In some implementations, fabricating a package includes several processes. FIGS. 7A-7D illustrate an exemplary sequence for providing or fabricating a package. In some implementations, the sequence of FIGS. 7A-7D may be used to provide or fabricate the package 100.

It should be noted that the sequence of FIGS. 7A-7D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 7A, illustrates a state after a substrate 102 and a carrier 700 are provided. The substrate 102 may be a first substrate. The substrate 102 may be coupled to the carrier 700. The carrier 700 may include an adhesive.

Stage 2 illustrates a state after the integrated device 101 is coupled to the substrate 102. The integrated device 101 may be coupled to the substrate 102 through a plurality of solder interconnects 110. A solder reflow process may be used to couple the integrated device 101 to the substrate 102. The integrated device 101 includes a plurality of through substrate vias 112. In some implementations, the integrated device 101 may include a back side metallization portion that is coupled to the plurality of through substrate vias 112. The back side metallization portion may include a plurality of metallization interconnects.

Stage 3 illustrates a state after the substrate 104 is coupled to the substrate 102 through a plurality of solder interconnects 160. The substrate 104 may be a second substrate. The substrate 104 may include an interconnection device 107 that is embedded in the substrate 104. The interconnection device 107 is coupled to the integrated device 101 through a plurality of solder interconnects 117. The interconnection device 107 maybe coupled to the back side of the integrated device 101 through the plurality of solder interconnects 117. A solder reflow process may be used to couple the substrate 104 to the substrate 102. A solder reflow process may be used to couple the interconnection device 107 to the integrated device 101.

Stage 4, as shown in FIG. 7B, illustrates a state after an encapsulation layer 106 is formed between the substrate 102 and the substrate 104. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 5 illustrates a state after the integrated device 103 is coupled to the substrate 104 and the interconnection device 107 through a plurality of solder interconnects 130. A solder reflow process may be used to couple the integrated device 103 to the substrate 104 and the interconnection device 107 through a plurality of solder interconnects 130. Stage 5 also illustrates a state after the integrated device 105 is coupled to the substrate 104 through a plurality of solder interconnects 150. A solder reflow process may be used to couple the integrated device 105 to the substrate 104 through a plurality of solder interconnects 150.

Stage 6, as shown in FIG. 7C, illustrates a state after an encapsulation layer 108 is formed and coupled to the substrate 104. The encapsulation layer 108 may at least partially encapsulate the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Stage 7 illustrates a state after the carrier 700 is decoupled from the substrate 102. The carrier 700 may be detaped from the substrate 102.

Stage 8, as shown in FIG. 7D, illustrates a state after a plurality of passive devices 128 are coupled to the substrate 102. The plurality of passive devices 128 may be coupled to the substrate 102 through a plurality of solder interconnects. The plurality of passive devices 128 may be coupled to the plurality of interconnects 122 through a plurality of solder interconnects.

Stage 9 illustrates a state after a plurality of solder interconnects 198 are coupled to the substrate 102. A solder reflow process may be used to couple the plurality of solder interconnects 198 to the plurality of interconnects 122 of the substrate 102. Stage 9 may illustrate the package 100. The package 100 may be fabricated one at a time or may be fabricated together as part of one or more wafers and then singulated into individual packages.

### Exemplary Sequence for Fabricating a Package

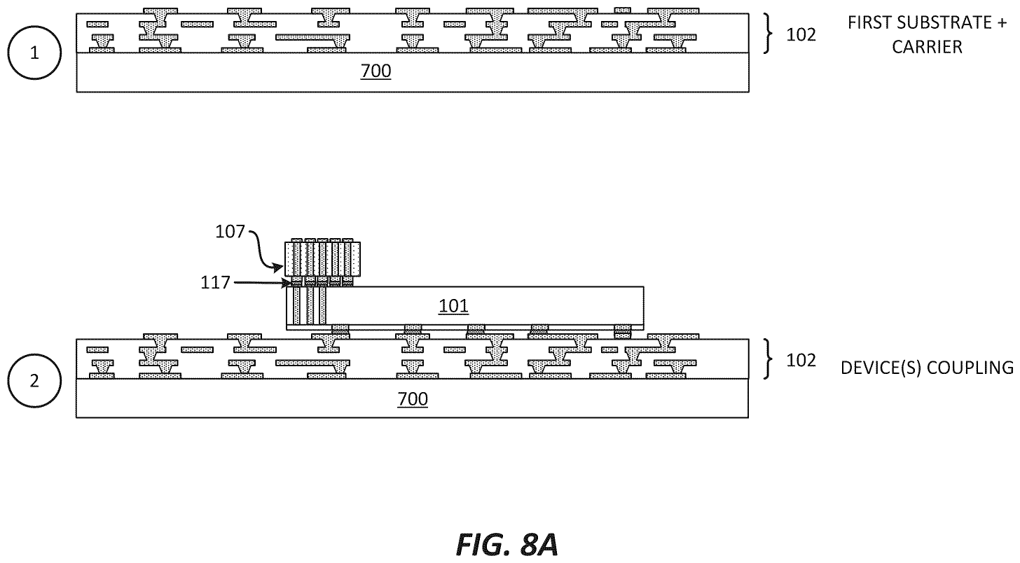

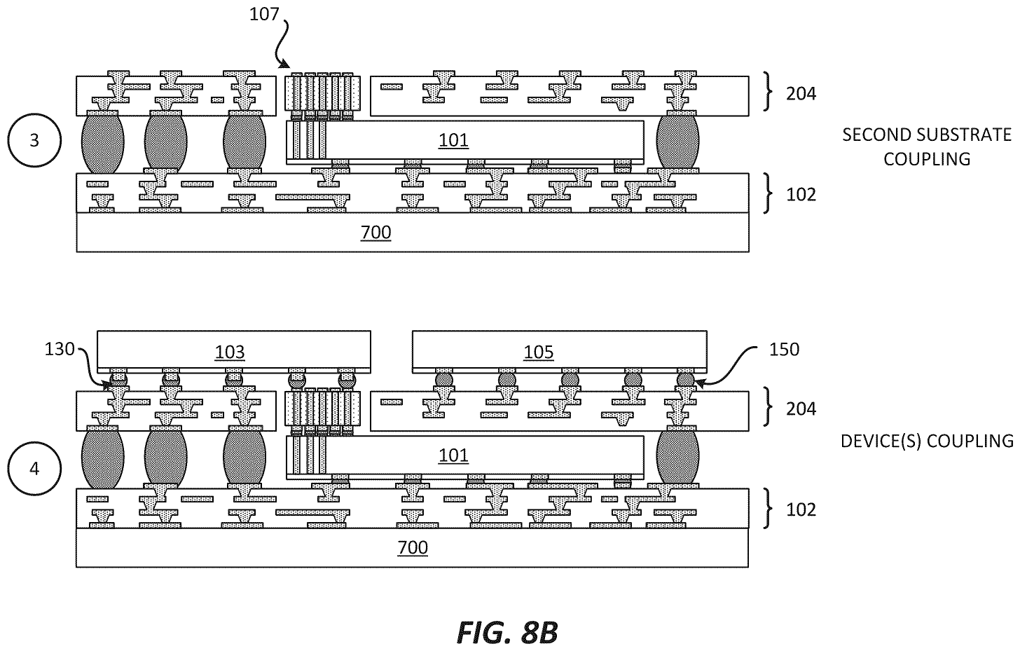

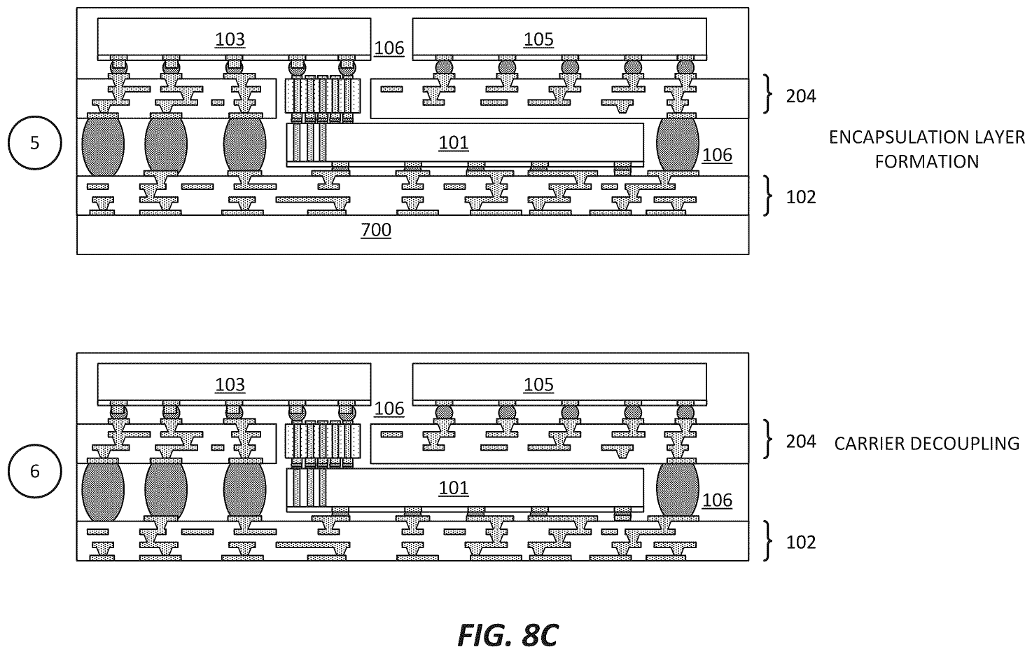

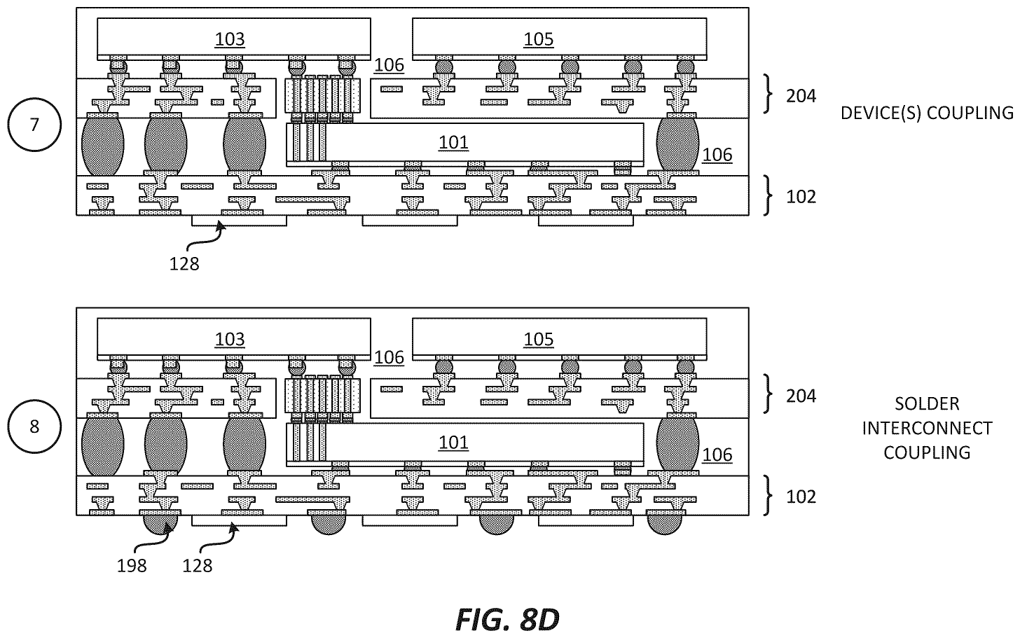

In some implementations, fabricating a package includes several processes. FIGS. 8A-8D illustrate an exemplary sequence for providing or fabricating a package. In some implementations, the sequence of FIGS. 8A-8D may be used to provide or fabricate the package 200.

It should be noted that the sequence of FIGS. 8A-8D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 8A, illustrates a state after a substrate 102 and a carrier 700 are provided. The substrate 102 may be a first substrate. The substrate 102 may be coupled to the carrier 700. The carrier 700 may include an adhesive.

Stage 2 illustrates a state after the integrated device 101 is coupled to the substrate 102. The integrated device 101 may be coupled to the substrate 102 through a plurality of solder interconnects 110. A solder reflow process may be used to couple the integrated device 101 to the substrate 102. The integrated device 101 includes a plurality of through substrate vias 112. In some implementations, the integrated device 101 may include a back side metallization portion that is coupled to the plurality of through substrate vias 112. The back side metallization portion may include a plurality of metallization interconnects. Stage 2 also illustrates a state after the interconnection device 107 is coupled to the back side of the integrated device 101 through a plurality of solder interconnects 117. In some implementations, the interconnection device 107 may be coupled to the integrated device 101 before the integrated device 101 is coupled to the substrate 102. In some implementations, the interconnection device 107 may be coupled to the integrated device 101 after the integrated device 101 is coupled to the substrate 102.

Stage 3, as shown in FIG. 8B, illustrates a state after the substrate 204 is coupled to the substrate 102 through a plurality of solder interconnects 160. The substrate 104 may be a second substrate. A solder reflow process may be used to couple the substrate 104 to the substrate 102.

Stage 4 illustrates a state after the integrated device 103 is coupled to the substrate 204 and the interconnection device 107 through a plurality of solder interconnects 130. A solder reflow process may be used to couple the integrated device 103 to the substrate 204 and the interconnection device 107 through a plurality of solder interconnects 130. Stage 4 also illustrates a state after the integrated device 105 is coupled to the substrate 204 through a plurality of solder interconnects 150. A solder reflow process may be used to couple the integrated device 105 to the substrate 204 through a plurality of solder interconnects 150.

Stage 5, as shown in FIG. 8C, illustrates a state after an encapsulation layer 106 is formed and coupled to the substrate 104. The encapsulation layer 106 may also be formed between the substrate 102 and the substrate 104. The encapsulation layer 106 may at least partially encapsulate the integrated device 101, the interconnection device 107, the integrated device 103 and the integrated device 105. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 6 illustrates a state after the carrier 700 is decoupled from the substrate 102. The carrier 700 may be detaped from the substrate 102.

Stage 7, as shown in FIG. 8D, illustrates a state after a plurality of passive devices 128 are coupled to the substrate 102. The plurality of passive devices 128 may be coupled to the substrate 102 through a plurality of solder interconnects. The plurality of passive devices 128 may be coupled to the plurality of interconnects 122 through a plurality of solder interconnects.

Stage 8 illustrates a state after a plurality of solder interconnects 198 are coupled to the substrate 102. A solder reflow process may be used to couple the plurality of solder interconnects 198 to the plurality of interconnects 122 of the substrate 102. Stage 8 may illustrate the package 200. The package 200 may be fabricated one at a time or may be fabricated together as part of one or more wafers and then singulated into individual packages.

### Exemplary Flow Diagram of a Method for Fabricating a Package

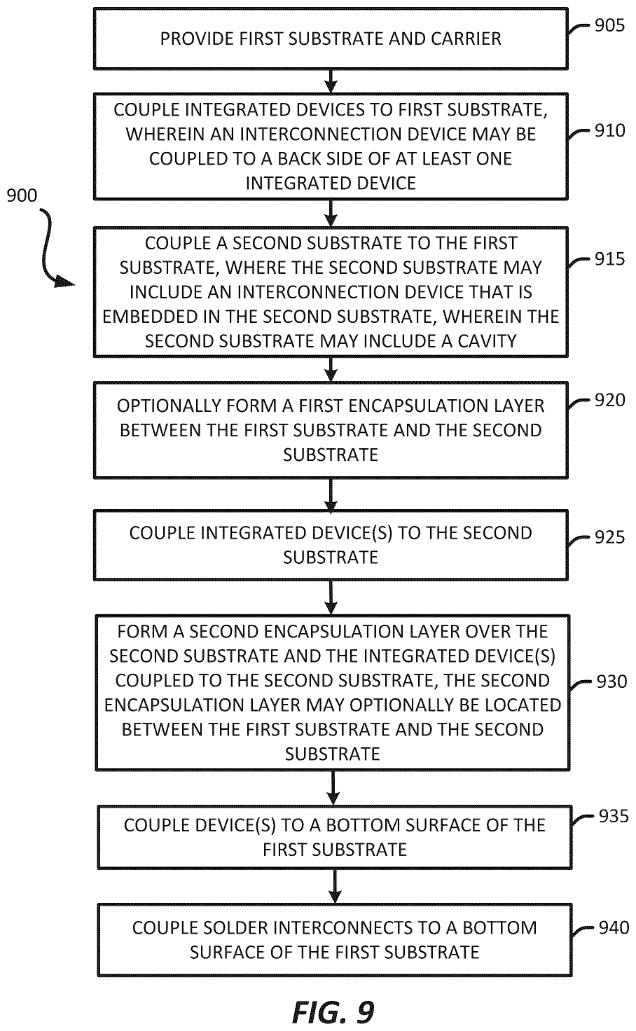

In some implementations, fabricating a package includes several processes. FIG. 9 illustrates an exemplary flow diagram of a method 900 for providing or fabricating a package. In some implementations, the method 900 of FIG. 9 may be used to provide or fabricate the package 100 described in the disclosure. However, the method 900 may be used to provide or fabricate any of the packages (e.g., 200, 300) described in the disclosure.

It should be noted that the method 900 of FIG. 9 may combine one or more processes in order to simplify and/or clarify the method for providing or fabricating a package. In some implementations, the order of the processes may be changed or modified.

The method provides (at 905) a first substrate and a carrier. Stage 1 of FIG. 7A, illustrates and describes an example of a state after a substrate 102 and a carrier 700 are provided. The substrate 102 may be a first substrate. The substrate 102 may be coupled to the carrier 700. The carrier 700 may include an adhesive.

The method couples (at 910) an integrated device to a first substrate. Stage 2 of FIG. 7A, illustrates a state after the integrated device 101 is coupled to the substrate 102. The integrated device 101 may be coupled to the substrate 102 through a plurality of solder interconnects 110. A solder reflow process may be used to couple the integrated device 101 to the substrate 102. The integrated device 101 includes a plurality of through substrate vias 112. In some implementations, the integrated device 101 may include a back side metallization portion that is coupled to the plurality of through substrate vias 112. The back side metallization portion may include a plurality of metallization interconnects.

The method couples (at 915) a second substrate to the first substrate. In some implementations, the second substrate may include an embedded interconnection device. In some implementations, the second substrate may include a cavity. Stage 3 of FIG. 7A, illustrates and describes an example of a state after the substrate 104 is coupled to the substrate 102 through a plurality of solder interconnects 160. The substrate 104 may be a second substrate. The substrate 104 may include an interconnection device 107 that is embedded in the substrate 104. The interconnection device 107 is coupled to the integrated device 101 through a plurality of solder interconnects 117. The interconnection device 107 maybe coupled to the back side of the integrated device 101 through the plurality of solder interconnects 117. A solder reflow process may be used to couple the substrate 104 to the substrate 102. A solder reflow process may be used to couple the interconnection device 107 to the integrated device 101.

The method optionally forms (at 920) an encapsulation layer between the first substrate and the second substrate. Stage 4 of FIG. 7B, illustrates and describes an example of a state after an encapsulation layer 106 is formed between the substrate 102 and the substrate 104. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

The method couples (at 925) integrated device(s) to the second substrate. Stage 5 of FIG. 7B, illustrates and describes an example of a state after the integrated device 103 is coupled to the substrate 104 and the interconnection device 107 through a plurality of solder interconnects 130. A solder reflow process may be used to couple the integrated device 103 to the substrate 104 and the interconnection device 107 through a plurality of solder interconnects 130. Stage 5 also illustrates a state after the integrated device 105 is coupled to the substrate 104 through a plurality of solder interconnects 150. A solder reflow process may be used to couple the integrated device 105 to the substrate 104 through a plurality of solder interconnects 150.

The method forms (at 930) an encapsulation layer that is coupled to the second substrate. The encapsulation layer may encapsulate the integrated devices. Stage 6 of FIG. 7C, illustrates and describes an example of a state after an encapsulation layer 108 is formed and coupled to the substrate 104. The encapsulation layer 108 may at least partially encapsulate the integrated device 103 and the integrated device 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

Once the encapsulation layer is formed, the method may decouple the first carrier from the first substrate. Stage 7 of FIG. 7C, illustrates and describes an example of a state after the carrier 700 is decoupled from the substrate 102. The carrier 700 may be detaped from the substrate 102.

The method couples (at 935) at least one passive devices to the first substrate. Stage 8 of FIG. 7D, illustrates and describes an example of a state after a plurality of passive devices 128 are coupled to the substrate 102. The plurality of passive devices 128 may be coupled to the substrate 102 through a plurality of solder interconnects. The plurality of passive devices 128 may be coupled to the plurality of interconnects 122 through a plurality of solder interconnects.

The method couples (at 940) a plurality of solder interconnects to the first substrate. Stage 9 of FIG. 7D, illustrates and describes an example of a state after a plurality of solder interconnects 198 are coupled to the substrate 102. A solder reflow process may be used to couple the plurality of solder interconnects 198 to the plurality of interconnects 122 of the substrate 102. Stage 9 may illustrate the package 100. The package 100 may be fabricated one at a time or may be fabricated together as part of one or more wafers and then singulated into individual packages.

### Exemplary Sequence for Fabricating a Substrate

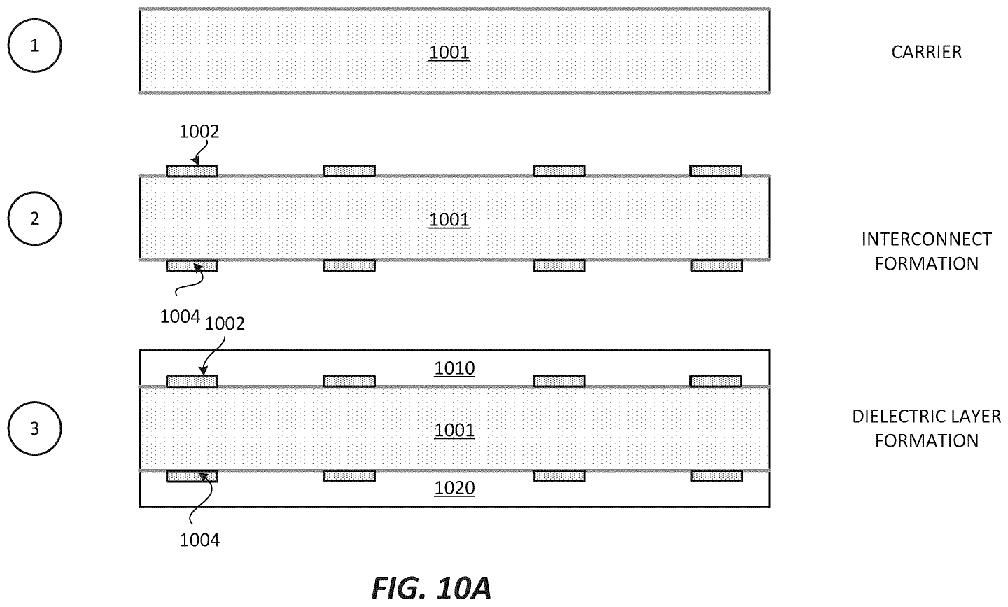

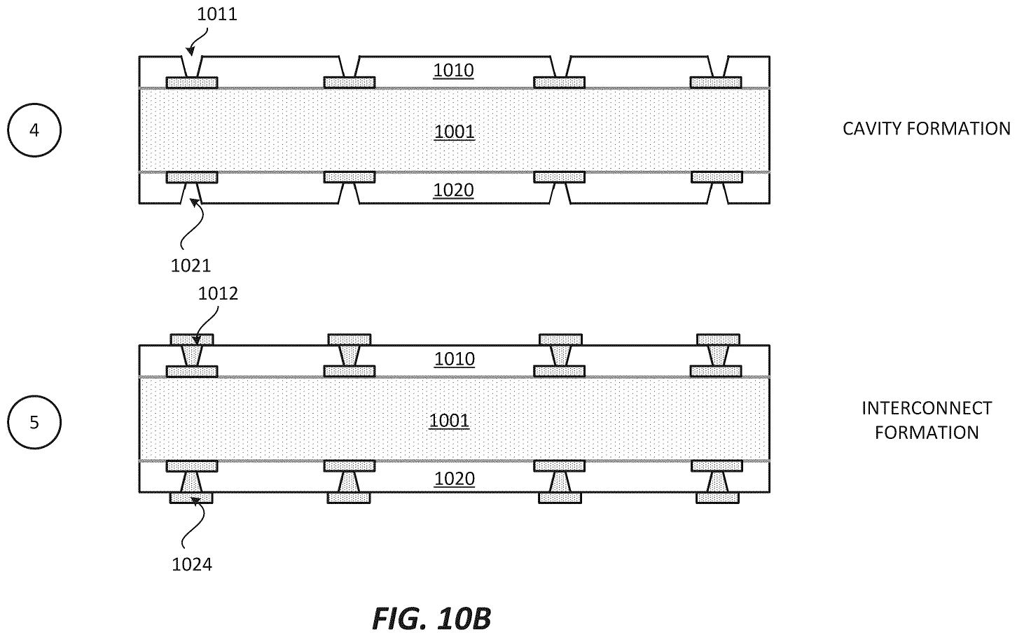

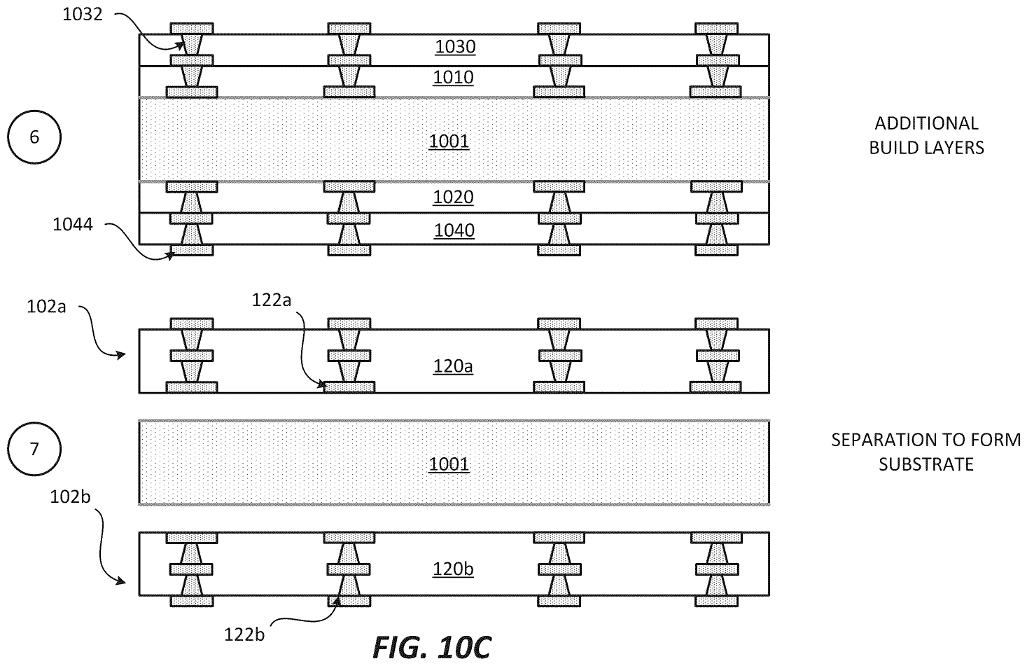

In some implementations, fabricating a substrate includes several processes. FIGS. 10A-10C illustrate an exemplary sequence for providing or fabricating a substrate. In some implementations, the sequence of FIGS. 10A-10C may be used to provide or fabricate the substrate 102. However, the process of FIGS. 10A-10C may be used to fabricate any of the substrates described in the disclosure. In some implementations, the process of FIGS. 10A-10C may be used to fabricate the interconnection device 407.

It should be noted that the sequence of FIGS. 10A-10C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 10A, illustrates a state after a carrier 1000 is provided. One or more seed layers may be located on surface(s) of the carrier 1000.

Stage 2 illustrates a state after a plurality of interconnects 1002 are formed on a first surface of the carrier 1000 and a plurality of interconnects 1004 are formed on a second surface of the carrier 1000. The plurality of interconnects 1002 and/or the plurality of interconnects 1004 may be located over the seed layers on the carrier 1000. A plating process and etching process may be used to form the plurality of interconnects 1002 and/or the plurality of interconnects 1004.

Stage 3 illustrates a state after a dielectric layer 1010 is formed over the carrier 1000 and the plurality of interconnects 1002. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

Stage 3 also illustrates a state after a dielectric layer 1020 is formed over the carrier 1000 and the plurality of interconnects 1004. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

Stage 4, as shown in FIG. 10B, illustrates a state after a plurality of cavities 1011 are formed in the dielectric layer 1010, and a plurality of cavities 1021 are formed in the dielectric layer 1020. The plurality of cavities 1011 and/or the plurality of cavities 1021 may be formed using an etching process (e.g., photo etching process) or laser process.

Stage 5 illustrates a state after interconnects 1012 are formed in and over the dielectric layer 1010, including in and over the plurality of cavities 1011. For example, a via, pad and/or traces may be formed. A plating process may be used to form the interconnects. Stage 5 also illustrates a state after interconnects 1024 are formed in and over the dielectric layer 1020, including in and over the plurality of cavities 1021. For example, a via, pad and/or traces may be formed. A plating process may be used to form the interconnects.

Stage 6, as shown in FIG. 10C, illustrates a state after a dielectric layer 1030 is formed over the dielectric layer 1010 and the plurality of interconnects 1012. A deposition and/or lamination process may be used to form the dielectric layer 1030. The dielectric layer 1030 may include prepreg and/or polyimide. The dielectric layer 1030 may include a photo-imageable dielectric. However, different implementations may use different materials for the dielectric layer. A plurality of interconnects 1032 may also be formed in the dielectric layer 1030 and on a surface of the dielectric layer 1030. Forming the plurality of interconnects 1032 may also include forming a plurality of cavities in the dielectric layer 1030. The plurality of cavities may be formed using an etching process (e.g., photo etching process) or laser process. A plating process may be used to form the interconnects.

Stage 6 also illustrates a state after a dielectric layer 1040 is formed over the dielectric layer 1020 and the plurality of interconnects 1024. A deposition and/or lamination process may be used to form the dielectric layer 1040. The dielectric layer 1040 may include prepreg and/or polyimide. The dielectric layer 1040 may include a photo-imageable dielectric. However, different implementations may use different materials for the dielectric layer. A plurality of interconnects 1044 may also be formed in the dielectric layer 1040 and on a surface of the dielectric layer 1040. Forming the plurality of interconnects 1044 may also include forming a plurality of cavities in the dielectric layer 1040. The plurality of cavities may be formed using an etching process (e.g., photo etching process) or laser process. A plating process may be used to form the interconnects.

Stage 7 illustrates a state after the dielectric layers are separated from the carrier 1001, leaving a substrate 102a and a substrate 102b. The substrate 102a may include at least one dielectric layer 120a and a plurality of interconnects 122a. The at least one dielectric layer 120a may represent the dielectric layer 1010 and/or the dielectric layer 1030. The plurality of interconnects 122a may represent the plurality of interconnects 1002, the plurality of interconnects 1012 and/or the plurality of interconnects 1022.

The substrate 102b may include at least one dielectric layer 120b and a plurality of interconnects 122b. The at least one dielectric layer 120b may represent the dielectric layer 1020 and/or the dielectric layer 1040. The plurality of interconnects 122b may represent the plurality of interconnects 1004, the plurality of interconnects 1024 and/or the plurality of interconnects 1044.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Substrate

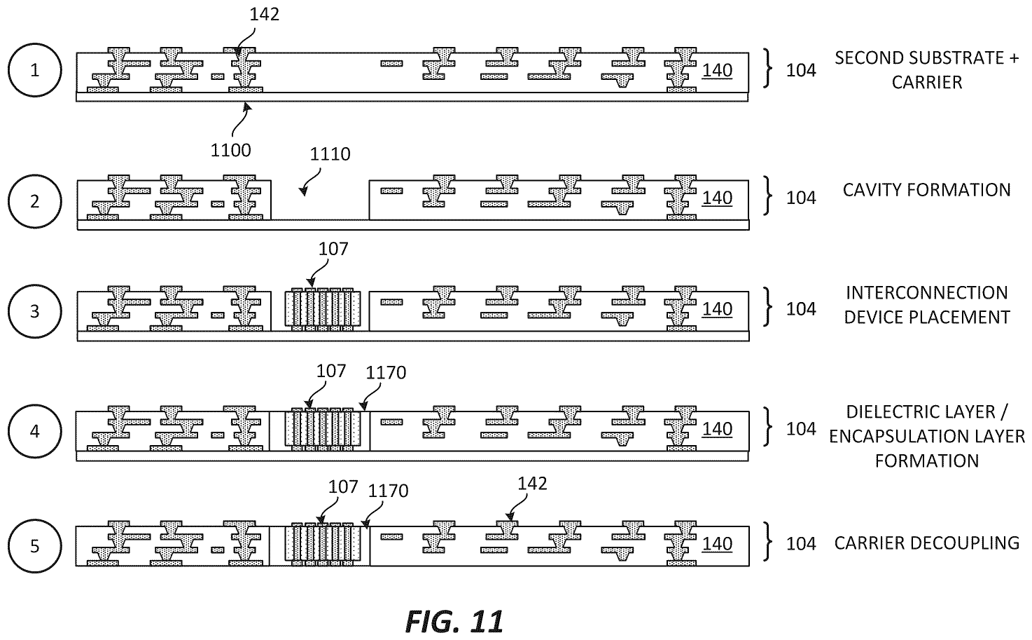

In some implementations, fabricating a substrate includes several processes. FIG. 11 illustrates an exemplary sequence for providing or fabricating a substrate that includes an interconnection device. In some implementations, the sequence of FIG. 11 may be used to provide or fabricate the substrate 104. However, the process of FIG. 11 may be used to fabricate any of the substrates described in the disclosure.

It should be noted that the sequence of FIGS. 10A-10C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 11, illustrates a state after a substrate 104 and a carrier 1100 are provided. The substrate 104 includes at least one dielectric layer 140 and a plurality of interconnects 142. The substrate 104 may be fabricated using the process of FIGS. 10A-10C. The substrate 104 may be coupled to the carrier 1100.

Stage 2 illustrates a state after a cavity 1110 is formed in the substrate 104. A laser ablation process may be used to form the cavity 1110.

Stage 3 illustrates a state after the interconnection device 107 is placed in the cavity 1110 of the substrate 104. The interconnection device 107 may be coupled to the carrier 1100 through an adhesive.

Stage 4 illustrates a state after a dielectric layer 1170 is formed in the cavity 1110. The dielectric layer 1170 may laterally surround the interconnection device 107. The dielectric layer 1170 may be the same material as the at least one dielectric layer 140. In some implementations, the dielectric layer 1170 may be indistinguishable from the at least one dielectric layer 140. In some implementations, the dielectric layer 1170 may be considered part of the at least one dielectric layer 140. In some implementations, instead of the dielectric layer 1170, an encapsulation layer may be used. The encapsulation layer may be similar to the encapsulation layer 106 and/or the encapsulation layer 108, as described in the disclosure.

Stage 5 illustrates a state after the carrier 1100 is decoupled from the substrate 104 and the interconnection device 107. The carrier 1100 may be detaped from the substrate 104.

### Exemplary Flow Diagram of a Method for Fabricating a Substrate

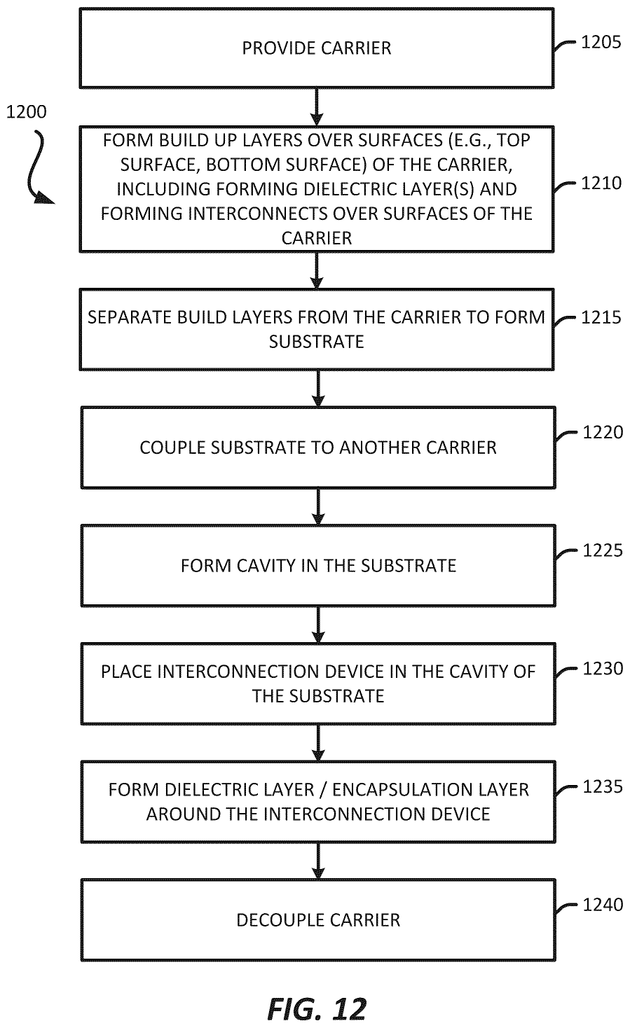

In some implementations, fabricating a substrate includes several processes. FIG. 12 illustrates an exemplary flow diagram of a method 1200 for providing or fabricating a substrate. In some implementations, the method 1200 of FIG. 12 may be used to provide or fabricate the substrate(s) of the disclosure. For example, the method 1200 of FIG. 12 may be used to fabricate the substrate 104 that includes an interconnection device.

It should be noted that the method 1200 of FIG. 12 may combine one or more processes in order to simplify and/or clarify the method for providing or fabricating a substrate. In some implementations, the order of the processes may be changed or modified.

The method provides (at 1205) a carrier. Stage 1 of FIG. 10A, illustrates and describes an example of a state after a carrier 1000 is provided. One or more seed layers may be located on surface(s) of the carrier 1000.

The method forms (at 1210) several build up layers over the carrier. The build up layers may include dielectric layers and a plurality of interconnects. Stage 2 of FIG. 10A through stage 6 of FIG. 10C, illustrates and describes an example of forming build layers that includes dielectric layers and a plurality of interconnects.

The method separates (at 1215) the dielectric layers and the plurality of interconnects from the carrier. Stage 7 of FIG. 10C illustrates and describes an example of dielectric layers separate from a carrier, which provides substrates with at least one dielectric layer and a plurality of interconnects.

The method couples (at 1220) a substrate to another carrier. Stage 1 of FIG. 11 illustrates and describes an example of a substrate 104 that is coupled to a carrier 1100. The substrate 104 includes at least one dielectric layer 140 and a plurality of interconnects.

The method forms (at 1225) a cavity in the substrate. Stage 2 of FIG. 11, illustrates and describes an example of a state after a cavity 1110 is formed in the substrate 104. A laser ablation process may be used to form the cavity 1110.

The method places (at 1230) an interconnection device in the cavity of the substrate. Stage 3 of FIG. 11, illustrates and describes an example of a state after the interconnection device 107 is placed in the cavity 1110 of the substrate 104. The interconnection device 107 may be coupled to the carrier 1100 through an adhesive.

The method forms (at 1235) a dielectric layer in the cavity of the substrate. The dielectric layer may laterally surround the interconnection device. Stage 4 of FIG. 11, illustrates and describes an example of a state after a dielectric layer 1170 is formed in the cavity 1110. The dielectric layer 1170 may laterally surround the interconnection device 107. The dielectric layer 1170 may be the same material as the at least one dielectric layer 140. In some implementations, the dielectric layer 1170 may be indistinguishable from the at least one dielectric layer 140. In some implementations, the dielectric layer 1170 may be considered part of the at least one dielectric layer 140. In some implementations, instead of the dielectric layer 1170, an encapsulation layer may be used. The encapsulation layer may be similar to the encapsulation layer 106 and/or the encapsulation layer 108, as described in the disclosure.

The method decouples (at 1240) the carrier from the substrate. Stage 5 of FIG. 11, illustrates and describes an example of a state after the carrier 1100 is decoupled from the substrate 104 and the interconnection device 107. The carrier 1100 may be detaped from the substrate 104.

### Exemplary Electronic Devices

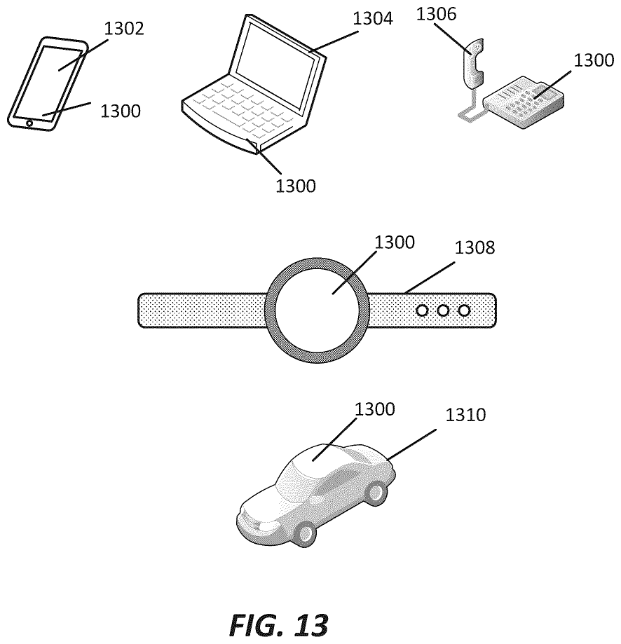

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6C, 7A-7D, 8A-8D, 9, 10A-10C and 11-13 may be rearranged and/or combined into a single component, process, feature or function or embodied in several components, processes, or functions. Additional elements, components, processes, and/or functions may also be added without departing from the disclosure. It should also be noted FIGS. 1-5, 6A-6C, 7A-7D, 8A-8D, 9, 10A-10C and 11-13 and its corresponding description in the present disclosure is not limited to dies and/or ICs. In some implementations, FIGS. 1-5, 6A-6C, 7A-7D, 8A-8D, 9, 10A-10C and 11-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate; a first integrated device coupled to the first substrate through at least a first plurality of solder interconnects, wherein the first integrated device comprises a plurality of through substrate vias; an interconnection device coupled to a back side of the first integrated device through a second plurality of solder interconnects; a second substrate coupled to the first substrate through at least a third plurality of solder interconnects; and a second integrated device coupled to the second substrate and the interconnection device.

Aspect 2: The package of aspect 1, wherein the second integrated device is coupled to the second substrate through a first set of solder interconnects from a fourth plurality of solder interconnects, and wherein the second integrated device is coupled to the interconnection device through a second set of solder interconnects from the fourth plurality of solder interconnects.

Aspect 3: The package of aspects 1 through 2, wherein the interconnection device is at least partially embedded in the second substrate.

Aspect 4: The package of aspects 1 through 2, wherein the interconnection device is located in a cavity of the second substrate.

Aspect 5: The package of aspects 1 through 2, further comprising a third substrate coupled to the first substrate through a fifth plurality of solder interconnects, wherein the interconnection device is located at least partially in a space between the second substrate and the third substrate.

Aspect 6: The package of aspects 1 through 5, wherein the interconnection device includes an interconnection substrate or an interposer.

Aspect 7: The package of aspects 1 through 6, wherein the interconnection device comprises a silicon substrate; and a plurality of interconnection interconnects located at least in the silicon substrate.

Aspect 8: The package of aspects 1 through 7, wherein the interconnection device comprises at least one dielectric layer; and a plurality of interconnection interconnects located in the at least one dielectric layer.

Aspect 9: The package of aspect 8, wherein the plurality of interconnection interconnects comprises a plurality of metallization interconnects.

Aspect 10: The package of aspects 1 through 9, wherein an electrical path between the second integrated device and the first integrated device comprises at least one interconnection interconnect from the plurality of interconnection interconnects, at least one solder interconnect from the second plurality of solder interconnects and at least one through substrate via from the plurality of through substrate vias.

Aspect 11: A method for fabricating a package. The method provides a first substrate. The method couples a first integrated device to the first substrate through at least a first plurality of solder interconnects, wherein the first integrated device comprises a plurality of through substrate vias. The method couples an interconnection device to a back side of the first integrated device through a second plurality of solder interconnects. The method couples a second substrate to the first substrate through at least a third plurality of solder interconnects. The method couples a second integrated device to the second substrate and the interconnection device.

Aspect 12: The method of aspect 11, wherein the second integrated device is coupled to the second substrate through a first set of solder interconnects from a fourth plurality of solder interconnects, and wherein the second integrated device is coupled to the interconnection device through a second set of solder interconnects from the fourth plurality of solder interconnects.

Aspect 13: The method of aspects 11 through 12, wherein the interconnection device is at least partially embedded in the second substrate.

Aspect 14: The method of aspects 11 through 12, wherein the interconnection device is located in a cavity of the second substrate.

Aspect 15: The method of aspects 11 through 12, further comprising a third substrate coupled to the first substrate through a fifth plurality of solder interconnects, wherein the interconnection device is located at least partially in a space between the second substrate and the third substrate.

Aspect 16: The method of aspects 11 through 15, wherein the interconnection device includes an interconnection substrate or an interposer.

Aspect 17: The method of aspects 11 through 16, wherein the interconnection device comprises a silicon substrate; and a plurality of interconnection interconnects located at least in the silicon substrate.

Aspect 18: The method of aspects 11 through 17, wherein the interconnection device comprises at least one dielectric layer; and a plurality of interconnection interconnects located in the at least one dielectric layer.

Aspect 19: The method of aspect 18, wherein the plurality of interconnection interconnects comprises a plurality of metallization interconnects.

Aspect 20: The method of aspects 11 through 19, wherein an electrical path between the second integrated device and the first integrated device comprises at least one interconnection interconnect from the plurality of interconnection interconnects, at least one solder interconnect from the second plurality of solder interconnects and at least one through substrate via from the plurality of through substrate vias.

Aspect 21: The package of aspects 1 through 10, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
a first integrated device coupled to the first substrate through at least a first plurality of solder interconnects, wherein the first integrated device comprises a plurality of through substrate vias;
an interconnection device coupled to a back side of the first integrated device through a second plurality of solder interconnects;
a second substrate coupled to the first substrate through at least a third plurality of solder interconnects; and
a second integrated device coupled to the second substrate and the interconnection device.

2. The package of claim 1,
wherein the second integrated device is coupled to the second substrate through a first set of solder interconnects from a fourth plurality of solder interconnects, and
wherein the second integrated device is coupled to the interconnection device through a second set of solder interconnects from the fourth plurality of solder interconnects.

3. The package of claim 1, wherein the interconnection device is at least partially embedded in the second substrate.

4. The package of claim 1, wherein the interconnection device is located in a cavity of the second substrate.

5. The package of claim 1, further comprising a third substrate coupled to the first substrate through a fifth plurality of solder interconnects, wherein the interconnection device is located at least partially in a space between the second substrate and the third substrate.

6. The package of claim 1, wherein the interconnection device includes an interconnection substrate or an interposer.

7. The package of claim 1, wherein the interconnection device comprises:
a silicon substrate; and
a plurality of interconnection interconnects located at least in the silicon substrate.

8. The package of claim 1, wherein the interconnection device comprises:
at least one dielectric layer; and
a plurality of interconnection interconnects located in the at least one dielectric layer.

9. The package of claim 8, wherein the plurality of interconnection interconnects comprises a plurality of metallization interconnects.

10. The package of claim 1, wherein an electrical path between the second integrated device and the first integrated device comprises at least one interconnection interconnect from the plurality of interconnection interconnects, at least one solder interconnect from the second plurality of solder interconnects and at least one through substrate via from the plurality of through substrate vias.

11. A method for fabricating a package, comprising:
providing a first substrate;
coupling a first integrated device to the first substrate through at least a first plurality of solder interconnects, wherein the first integrated device comprises a plurality of through substrate vias;
coupling an interconnection device to a back side of the first integrated device through a second plurality of solder interconnects;
coupling a second substrate to the first substrate through at least a third plurality of solder interconnects; and
coupling a second integrated device to the second substrate and the interconnection device.

12. The method of claim 11,
wherein the second integrated device is coupled to the second substrate through a first set of solder interconnects from a fourth plurality of solder interconnects, and
wherein the second integrated device is coupled to the interconnection device through a second set of solder interconnects from the fourth plurality of solder interconnects.

13. The method of claim 11, wherein the interconnection device is at least partially embedded in the second substrate.

14. The method of claim 11, wherein the interconnection device is located in a cavity of the second substrate.

15. The method of claim 11, further comprising a third substrate coupled to the first substrate through a fifth plurality of solder interconnects, wherein the interconnection device is located at least partially in a space between the second substrate and the third substrate.

16. The method of claim 11, wherein the interconnection device includes an interconnection substrate or an interposer.

17. The method of claim 11, wherein the interconnection device comprises:
a silicon substrate; and
a plurality of interconnection interconnects located at least in the silicon substrate.

18. The method of claim 11, wherein the interconnection device comprises:
at least one dielectric layer; and
a plurality of interconnection interconnects located in the at least one dielectric layer.

19. The method of claim 18, wherein the plurality of interconnection interconnects comprises a plurality of metallization interconnects.

20. The method of claim 11, wherein an electrical path between the second integrated device and the first integrated device comprises at least one interconnection interconnect from the plurality of interconnection interconnects, at least one solder interconnect from the second plurality of solder interconnects and at least one through substrate via from the plurality of through substrate vias.
